(19) United States
(12) Patent Application Publication
(10) Pub. No.: US 2008/0283901 A1
(43) Pub. Date: Nov. 20, 2008

(54) NONVOLATILE MEMORY WITH MULTIPLE BITS PER CELL

(76) Inventor: Andrew J. Walker, Mountain View, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/749,081

(22) Filed: May 15, 2007

(51) Int. Cl. H01L 29/792; G11C 11/34

(52) U.S. Cl. 257/324; 365/185.21; 257/E29.309

(57) ABSTRACT

A dual-gate memory cell includes a first memory device and a second memory device each having a gate electrode and a charge storage gate dielectric layer. The first and second memory devices share a channel region and source and drain regions. Such a memory cell is read by sensing the charge in one of the dielectric layers by applying a first voltage in the gate electrode associated with the dielectric layer sensed, and applying a second voltage substantially different than the first voltage in the other dielectric layer.

### BACKGROUND OF THE INVENTION

1. Field of the Invention

The present invention relates to dual-gate non-volatile memories. In particular, the present invention relates to dual-gate flash memory cells each of which can store multiple bits simultaneously.

2. Discussion of the Related Art

The article “A 2-Bit MONOS Nonvolatile Memory Cell Based on Asymmetric Double Gate MOSFET Structure”, by K. H. Yuen et al, published in IEEE Electron Device Letters, vol. 24, pp. 518-520, August 2003, discloses a NOR-based dual-gate semiconductor structure having top and bottom gates doped to opposite conductivity types, and which is read-out by applying the same voltages to the top and bottom gates. The structure disclosed in the Yuen article requires a work function difference between the two gate electrodes to distinguish between the charge stored in the two gate dielectric layers.

### SUMMARY OF THE INVENTION

According to one embodiment of the present invention, a dual-gate device includes first and second memory devices having their threshold voltages determined by the charge stored in their respective gate dielectrics. The respective threshold voltages of the dual-gate device may be sensed during a read operation, and thereby allows a higher memory density to be achieved.

According to one embodiment of the present invention, the dual-gate memory cell includes a first memory device and a second memory device each having a gate electrode and a charge storage gate dielectric layer. The first and second memory devices share a channel region and source and drain regions. Such a memory cell is read by sensing the charge in one of the gate dielectric layers by applying a first voltage in the gate electrode associated with the dielectric layer sensed, and applying a second voltage substantially different than the first voltage in the other gate dielectric layer.

The present invention is better understood upon consideration of the detailed description in conjunction with the accompanying drawings.

### BRIEF DESCRIPTION OF THE DRAWINGS

FIG. 1 shows a cross-section of dual-gate memory cell 100 including a first memory device and a second memory device, according to one embodiment of the present invention.

FIG. 2 is a cross section of a NAND string 200 formed by a number of dual-gate memory cells, in accordance with one embodiment of the present invention.

FIG. 3 is a drain-source current versus gate voltage graph which illustrates the respective threshold voltages for a programmed device and an erased device, for both the bottom device (e.g., first memory device) and the top device (e.g., second memory device) of a dual-gate memory cell.

### DETAILED DESCRIPTION OF THE PREFERRED EMBODIMENTS

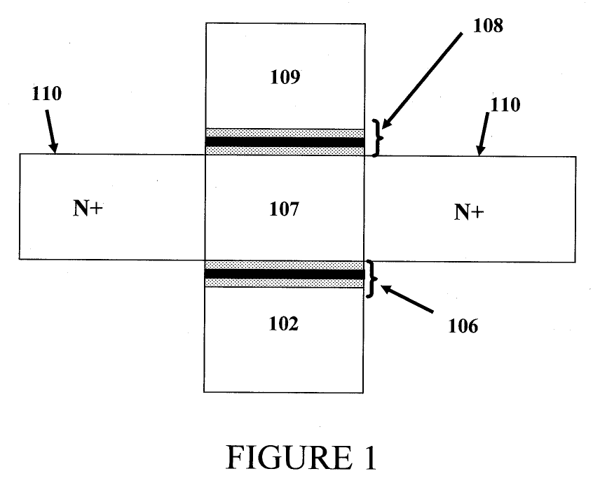

The present invention provides a memory circuit formed by an array of dual-gate memory cells each capable of storing multiple bits of information. FIG. 1 shows a cross-section of dual-gate memory cell 100 including a first memory device and a second memory device, according to one embodiment of the present invention. As shown in FIG. 1, dual-gate memory cell includes first gate electrode 102, first charge storage gate dielectric layer 106, lightly doped channel region 107, N⁺ source-drain regions 110, second charge storage gate dielectric layer 108 and second gate electrode 109. The first memory device includes first gate electrode 102 and first charge storage gate dielectric layer 106. The second memory device includes second gate electrode 109 and second charge storage gate dielectric layer 108. Lightly doped channel region 107 and N⁺ source-drain regions 110 are shared between the memory devices.

First gate electrode 102 and second gate electrode 109 may each be formed of a conductor, such as doped polysilicon, tungsten, tantalum nitride, tungsten nitride or a combination of two or more of these materials.

First charge storage gate dielectric layer 106 and second charge storage gate electrode layer 108 may each be provided by a stack of dielectric materials, such as a stack formed by successive layers of silicon dioxide, silicon nitride and silicon dioxide. Alternatively, the silicon nitride layer may be replaced by a silicon oxynitride layer or a graded layer of silicon nitride having spatial variations in oxygen content. Still alternatively, in place of silicon nitride, silicon nanocrystals, germanium or a metal such as tungsten may also be used. Similarly, either of the silicon dioxide layers may be provided instead by aluminum oxide or another high dielectric constant (“high k”) material. In one implementation, first and second charge storage gate dielectric layers 106 and 108 each include a 50-200 Å thick aluminum oxide layer, a 50-150 Å thick silicon nitride layer, and a 15-60 Å thick silicon dioxide layer, with the aluminum oxide layer being located in the gate dielectric layer adjacent its respective gate electrode.

Lightly doped channel region 107 may be provided by a material consisting of amorphous silicon, germanium, polycrystalline silicon, a combination of amorphous silicon and germanium, or a combination of polycrystalline silicon and germanium. The channel region may be doped either n-type or p-type to an impurity concentration between 10¹⁴ cm⁻³ to 10¹⁹ cm⁻³.

Source and drain regions 110 are heavily doped amorphous silicon, germanium, polycrystalline silicon, a combination of amorphous silicon and germanium, or a combination of polycrystalline silicon and germanium, that is doped either p-type or n-type to a concentration between 10¹⁹ cm⁻³ to 10²¹ cm⁻³.

To program this memory cell, a ground voltage or a small voltage is applied to one of source and drain region 110 (designated the “drain region”) and the other source and drain region 110 (designated the “source” region) is allowed to electrically float or is grounded or is applied a small voltage. Depending on whether charge is to be stored in first charge storage gate dielectric 106 or second charge storage gate dielectric layer 108 is to be programmed, a programming voltage between 9V and 18V (e.g., 15V) is applied to gate electrode 102 or gate electrode 109. The gate electrode for the memory device dual-gate memory device 100 that is not to be programmed may be maintained at a voltage lower than the programming voltage. In this way, a charge inversion layer is formed in channel region 107 (e.g., active semiconductor layer 107) close to the gate electrode of the memory device being programmed. Programming is achieved by tunneling electric charge from the inversion layer in channel region 107 of the memory device being programmed to the charge trapping sites within the memory device's gate dielectric layer (such as dielectric layer 108).

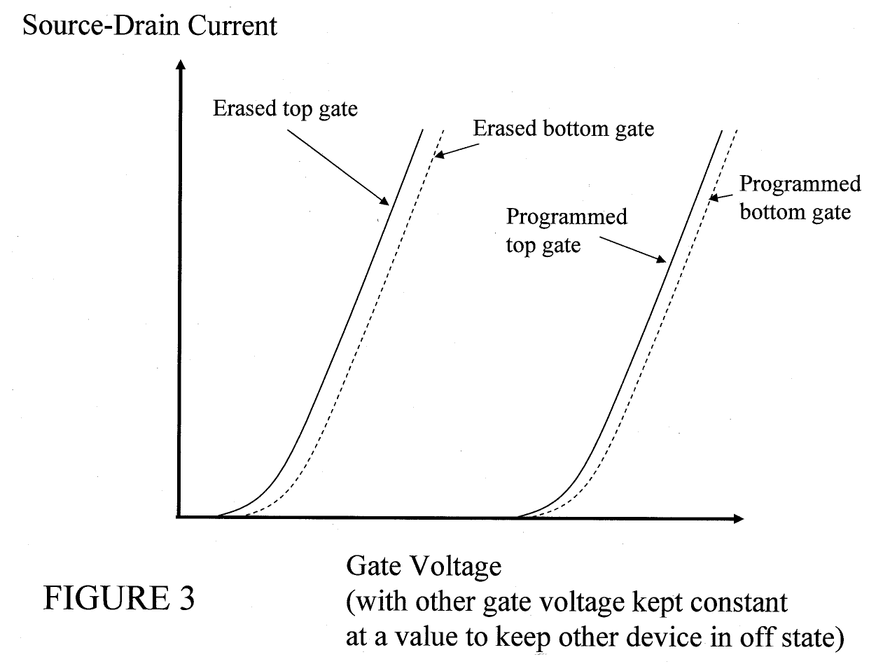

The threshold voltage for a programmed memory device of the dual-gate memory cell is different, according to whether or not charge is stored in the associated charge storage gate dielectric layer. FIG. 3 is a drain-source current versus gate voltage graph which illustrates the different threshold voltages for a programmed device and an erased device, for both the bottom device (e.g., first memory device) and the top device (e.g., second memory device) of a dual-gate memory cell. While one memory device of a dual-gate memory cell gate is read, a sub-threshold constant voltage is applied to the other gate electrode such as to keep the memory device in the “off” state, regardless of the memory device's programmed state. To read a memory device (say, the first memory device) in a dual-gate memory cell, its gate electrode is applied a voltage intermediate between the threshold voltages of the programmed and the erased state. The resulting source-drain current (or its absence) is used to determined whether or not charge is stored in the corresponding gate dielectric layer. The gate electrode in the other memory device (e.g., the second memory device) is applied a subthreshold voltage

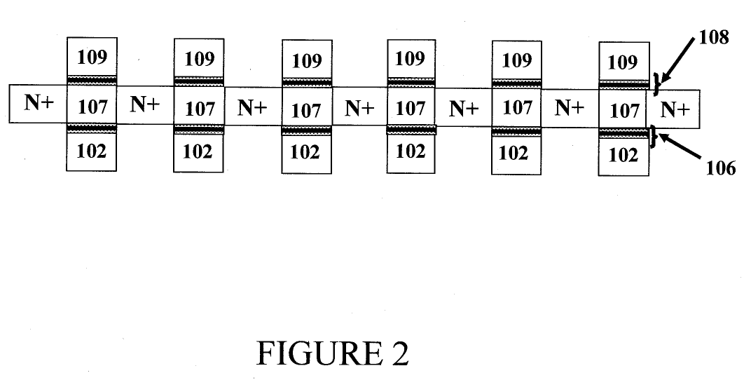

Memory cell 100 of FIG. 1 may be used as a building block for larger memory circuits. For example, FIG. 2 is a cross section of a NAND string 200 formed by a number of dual-gate memory cells, in accordance with one embodiment of the present invention. To program or read a memory device in a dual-gate memory cell, the memory cells in NAND string 200, other than the memory cell to be programmed or read, are each rendered conducting to serve as access gates to the memory cell to be programmed or read.

To read, at least the memory cell opposite the cell to be read is rendered non-conducting by applying a subthreshold voltage to its gate. A read voltage that is between the programmed and erased threshold voltages of any of the devices, is applied to the gate of the memory cell to be read. Then any combination of voltages is used to provide a conducting path through all other channel regions.

To program a memory cell, any combination of voltages is applied to the gates of the devices that lie between a ground or close-to-ground node and the memory cell to be programmed so as to make a conducting path between the cell to be programmed and the ground or close to ground node. A large positive voltage (between 10V and 22V) is then applied to the gate of the cell to be programmed causing charge to be trapped in the memory cell's gate dielectric.

The above detailed description is provided to illustrate specific embodiments of the present invention. Numerous modifications and variations with in the scope of the present invention are possible. The present invention is set forth in the following claims.

I claim:

1. A dual-gate memory cell, comprising a first memory device and a second memory device each having a gate electrode and a charge storage gate dielectric layer, wherein the first and second memory devices share a channel region and source and drain regions, and wherein the charge stored in the charge storage gate dielectric layers of the first memory device and the second memory device are independently sensed.

2. A dual-gate memory cell as in claim 1, wherein the gate electrodes of the first and memory devices are adapted to receive independently imposed voltages.

3. A dual-gate memory cell as in claim 1, wherein the charge storage gate electrodes each comprise charge storage layer between insulators layers.

4. A dual-gate memory cell as in claim 3, wherein the insulator layers comprises material with a high dielectric constant.

5. A dual-gate memory cell as in claim 3, wherein the insulator layers comprise one or more of silicon oxide and aluminum oxide.

6. A dual-gate memory cell as in claim 3, wherein the charge storage layer comprises one or more of silicon nitride, silicon oxynitride, a graded layer of silicon nitride having spatial variations in oxygen content, silicon nanocrystals, germanium or a metal.

7. A dual-gate memory cell as in claim 6, wherein the metal comprises tungsten.

8. A memory string comprising two or more dual-gate memory cells each being provided as in the dual-gate memory cell of claim 1.

9. A method for reading a dual-gate memory cell, the dual-gate memory cell comprising a first memory device and a second memory device each having a gate electrode and a charge storage gate dielectric layer, and sharing a channel region and source and drain regions, the method comprising:
Storing charge in the charge storage gate dielectric layers of the first memory device and the second memory device; and
sensing the charge in one of the dielectric layers by applying a first voltage in the gate electrode associated with the dielectric layer sensed, and applying a second voltage substantially different than the first voltage in the dielectric layer other than the dielectric layer sensed.

10. A method as in claim 9, wherein the first voltage is selected based on the different threshold voltages of the memory device as a result of the presence and absence of charge stored in the dielectric layer sensed.

11. A method as in claim 9, wherein the gate electrodes of the first and memory devices are adapted to receive independently imposed voltages.

12. A method as in claim 9, wherein the charge storage gate electrodes each comprise charge storage layer between insulators layers.

13. A method as in claim 12, wherein the insulator layers comprises material with a high dielectric constant.

14. A method as in claim 12, wherein the insulator layers comprise one or more of silicon oxide and aluminum oxide.

15. A method as in claim 12, wherein the charge storage layer comprises one or more of silicon nitride, silicon oxynitride, a graded layer of silicon nitride having spatial variations in oxygen content, silicon nanocrystals, germanium or a metal.

16. A method as in claim 15, wherein the metal comprises tungsten.
